(19) United States
(12) Patent Application Publication
(10) Pub. No.: US 2026/0185966 A1
(43) Pub. Date: Jul. 2, 2026

(54) PULSE WIDTH MODULATION CONTROL DEVICE AND ULTRASOUND CONTROL SYSTEM AND METHOD

(71) Applicant: INDUSTRIAL TECHNOLOGY RESEARCH INSTITUTE, Hsinchu (TW)

(72) Inventors: Wen-Chuan CHEN, Hsinchu County (TW); Kuei-Ming LEE, Hsinchu City (TW); Cheng-Xue WU, Kaohsiung City (TW); Kevin CHANDRA, Hsinchu City (TW); Wan-Lung LEE, Zhubei City (TW); Yin-Ling KUO, Hsinchu City (TW)

(73) Assignee: INDUSTRIAL TECHNOLOGY RESEARCH INSTITUTE, Hsinchu (TW)

(21) Appl. No.: 19/266,859

(22) Filed: Jul. 11, 2025

(30) Foreign Application Priority Data
Dec. 27, 2024 (TW) 113151195

(51) Int. Cl. G01N 29/34; G01N 29/30; H03K 7/08

(52) U.S. Cl. CPC G01N 29/348; G01N 29/30; H03K 7/08

(57) ABSTRACT

The present disclosure proposes a pulse width modulation control device and ultrasound control system and method. The pulse width modulation control device includes first and second registers, an adder, a sawtooth wave generator and a comparator. The adder replaces a remainder value stored by the second register with a summed value of a target pulse count stored by the first register and the remainder value when the summed value is smaller than a maximum pulse count, and replaces the remainder value with a difference value between the summed value and the maximum pulse count and generates a pulse trigger signal when the summed value is not smaller than the maximum pulse count. The sawtooth wave generator generates a sawtooth wave signal based on the pulse trigger signal. The comparator outputs a pulse width modulation signal based on a comparison result between the sawtooth wave signal and an ultrasound control signal.

### CROSS-REFERENCE TO RELATED APPLICATIONS

This non-provisional application claims priority under 35 U.S.C. § 119(a) on Patent Application No(s). 113151195 filed in Republic of China (ROC) on Dec. 27, 2024, the entire contents of which are hereby incorporated by reference.

### BACKGROUND

### 1. Technical Field

This technical field relates to a pulse width modulation (PWM) control device and ultrasound control system and method.

### 2. Related Art

Conventional ultrasonic controllers typically control the output duty cycle through pulse width modulation (PWM) signals. This technique leverages the periodic variations of target sine wave and sawtooth wave signals to adjust the duty cycle of the PWM signal, thereby achieving control over the frequency and waveform of the output signal. Additionally, the combination of PWM technology with the characteristics of sawtooth and sine wave enables the provision of output signals across various ultrasonic application scenarios.

### SUMMARY

According to one or more embodiment of this disclosure, a pulse width modulation (PWM) control device includes: a first register, a second register, an adder, a sawtooth wave generator and a comparator. The first register is configured to store a target pulse count. The second register is configured to store a remainder value. The adder is connected to the first register and the second register, and is configured to obtain a maximum pulse count according to a system clock period, add the target pulse count and the remainder value to obtain a summed value each time a system clock occurs, replace the remainder value of the second register with the summed value when the summed value is smaller than the maximum pulse count, replace the remainder value of the second register with a difference value between the summed value and the maximum pulse count and generate a pulse trigger signal when the summed value is greater than or equal to the maximum pulse count. The sawtooth wave generator is connected to the adder, and is configured to generate a sawtooth wave signal based on the pulse trigger signal. The comparator is connected to the sawtooth wave generator, and is configured to determine a pulse width according to a comparison result between the sawtooth wave signal and an ultrasound control signal, and output a PWM signal based on the pulse width.

According to one or more embodiment of this disclosure, an ultrasound control system includes: a frequency compensator, a pulse width modulation (PWM) control device and a sinusoidal signal generator. The frequency compensator is configured to output an ultrasound control signal. The PWM control device is connected to the frequency compensator, and includes: a first register, a second register, an adder, a sawtooth wave generator and a comparator. The first register is configured to store a target pulse count. The second register is configured to store a remainder value. The adder is connected to the first register and the second register, and is configured to obtain a maximum pulse count according to a system clock period, add the target pulse count and the remainder value to obtain a summed value each time a system clock occurs, replace the remainder value of the second register with the summed value when the summed value is smaller than the maximum pulse count, replace the remainder value of the second register with a difference value between the summed value and the maximum pulse count and generate a pulse trigger signal when the summed value is greater than or equal to the maximum pulse count. The sawtooth wave generator is connected to the adder, and is configured to generate a sawtooth wave signal based on the pulse trigger signal. The comparator is connected to the sawtooth wave generator, and is configured to determine a pulse width according to a comparison result between the sawtooth wave signal and the ultrasound control signal, and output a PWM signal based on the pulse width. The sinusoidal signal generator is connected to the PWM control device, and is configured to output a sinusoidal signal according to the PWM signal.

According to one or more embodiment of this disclosure, an ultrasound control method includes: outputting, by a frequency compensator, an ultrasound control signal; adding, by an adder, a target pulse count and a remainder value to obtain a summed value; obtaining, by the adder, a maximum pulse count according to a system clock period; replacing, by the adder, the remainder value with the summed value when determining, by the adder, the summed value is smaller than the maximum pulse count; replacing, by the adder, the remainder value with a difference value between the summed value and the maximum pulse count, and generating, by the adder, a pulse trigger signal when determining, by the adder, the summed value is greater than or equal to the maximum pulse count; generating, by a sawtooth wave generator, a sawtooth wave signal based on the pulse trigger signal; determining, by a comparator, a pulse width according to a comparison result between the sawtooth wave signal and the ultrasound control signal, and outputting, by the comparator, a pulse width modulation (PWM) signal based on the pulse width; and outputting, by a sinusoidal signal generator, a sinusoidal signal according to the PWM signal.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a block diagram illustrating a pulse width modulation control device according to an embodiment of the present disclosure;

FIG. 2 is a block diagram illustrating an ultrasound control system according to an embodiment of the present disclosure;

FIG. 3 is a flow chart illustrating an ultrasound control method according to an embodiment of the present disclosure;

FIG. 4 is a schematic diagram illustrating a half cycle ultrasound control signal, a pulse trigger signal, a sawtooth wave signal, a pulse width of a pulse width modulation signal and a system clock according to an embodiment of the present disclosure;

FIG. 5 is a diagram showing the pulse width modulation signal and a sinusoidal signal; and

FIG. 6 is a block diagram illustrating a sinusoidal signal generator according to an embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

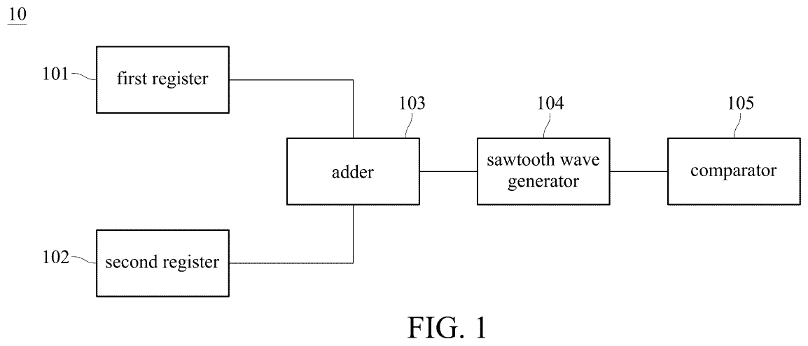

Please refer to FIG. 1, wherein FIG. 1 is a block diagram illustrating a pulse width modulation control device according to an embodiment of the present disclosure. As shown in FIG. 1, the pulse width modulation (PWM) control device 10 includes a first register 101, a second register 102, an adder 103, a sawtooth wave generator 104 and a comparator 105. The first register 101 and the second register 102 are connected to the adder 103, the adder 103 is connected to the sawtooth wave generator 104, and the sawtooth wave generator 104 is connected to the comparator 105.

The first register 101 is configured to store a target pulse count, wherein the target pulse count may be a preset count of the PWM signal generated in a unit cycle, and the target pulse count may be any integer number ranges from 1 to a maximum pulse count. The second register 102 is configured to store a remainder value. The adder 103 is configured to obtain the maximum pulse count according to a system clock period. The adder 103 adds the target pulse count and the remainder value each time a system clock occurs to obtain a summed value. The adder 103 replaces the remainder value of the second register 102 with the summed value when the summed value is smaller than the maximum pulse count, replaces the remainder value of the second register 102 with a difference value between the summed value and the maximum pulse count and generates a pulse trigger signal when the summed value is greater than or equal to the maximum pulse count.

The sawtooth wave generator 104 may include a waveform generator. The sawtooth wave generator 104 is configured to generate a sawtooth wave signal based on the pulse trigger signal. The comparator 105 is configured to determine a pulse width according to a comparison result between the sawtooth wave signal and the ultrasound control signal, and output the PWM signal based on the pulse width. The control objective of the PWM control device 10 is to generate PWM signals with a quantity equal to the target pulse count within a unit cycle corresponding to the half-cycle period of the ultrasound control signal. The adder 103 may generate one pulse signal each time the summed value obtained by the adder 103 is equal to or greater than the maximum pulse count.

The PWM signal generated by the PWM control device according to one or more embodiments of the present disclosure may be used in conjunction with a sinusoidal signal generator to generate alternating current (AC) voltage with specific sine wave frequency. The AC voltage is then converted into vibrational mechanical energy by the ultrasonic transducer. Accordingly, since the amplitude of the target sinusoidal signal is positively correlated with the pulse width of the PWM signal, the PWM control device according to one or more embodiments of the present disclosure may control the output power of the ultrasound controller by adjusting the voltage (amplitude) of the target sinusoidal signal. At the same time, based on the summed value of the target pulse count and the remainder value stored in the registers, the pulse trigger signal is output, enabling synchronization between the PWM signal and the sinusoidal signal, to ensure that the expected number of PWM signals is generated within a unit cycle, thereby aligning the output PWM signal with the half cycle of the sinusoidal signal to be controlled. As a result, the issue of asynchronous PWM signal affecting output frequency stability and reliability may be resolved.

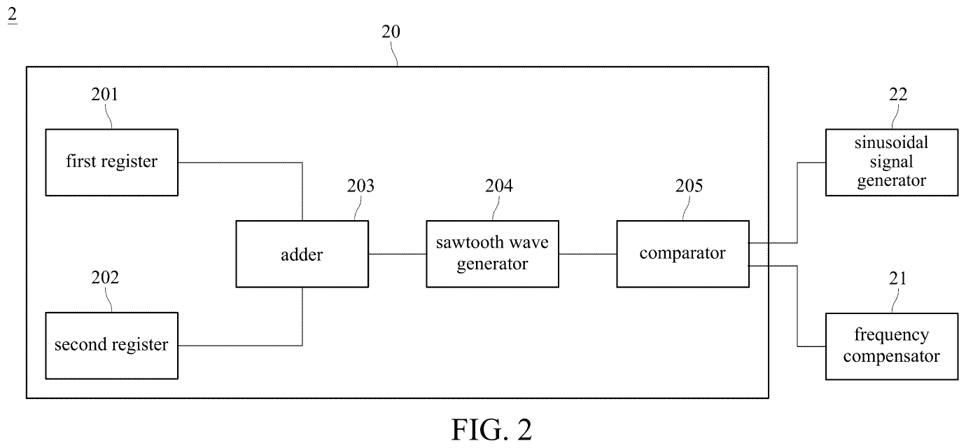

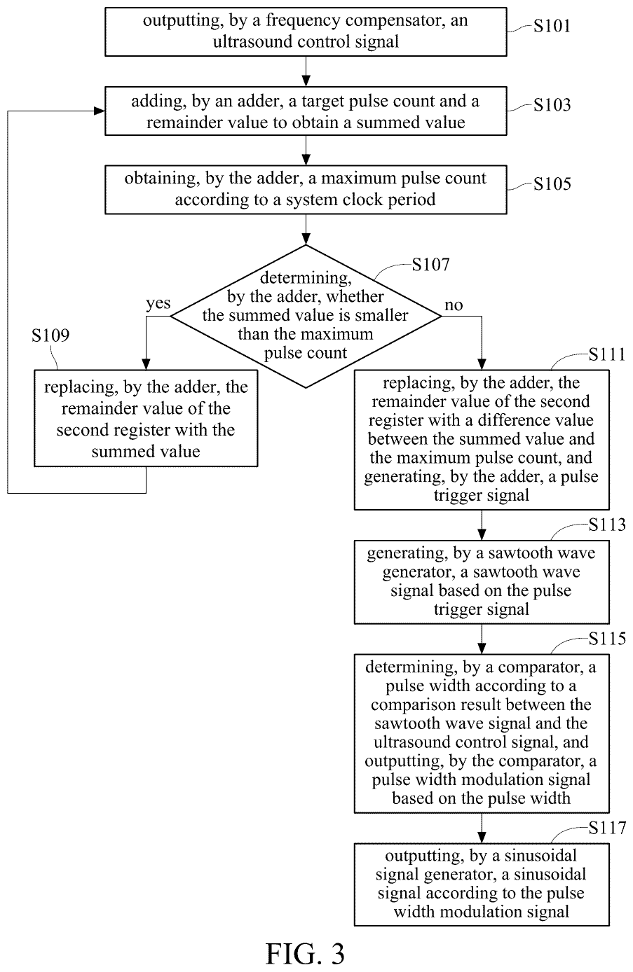

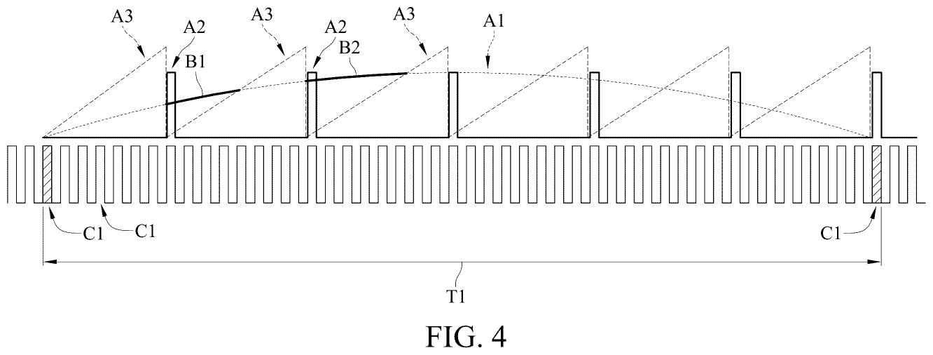

Please refer to FIG. 2, FIG. 3 and FIG. 4, wherein FIG. 2 is a block diagram illustrating an ultrasound control system according to an embodiment of the present disclosure, FIG. 3 is a flow chart illustrating an ultrasound control method according to an embodiment of the present disclosure, and FIG. 4 is a schematic diagram illustrating a half cycle ultrasound control signal, a pulse trigger signal, a sawtooth wave signal, a pulse width of a PWM signal and a system clock according to an embodiment of the present disclosure. As shown in FIG. 2, the ultrasound control system 2 includes a PWM control device 20, a frequency compensator 21 and a sinusoidal signal generator 22.

The PWM control device 20 includes a first register 201, a second register 202, an adder 203, a sawtooth wave generator 204 and a comparator 205. The first register 201 and the second register 202 are connected to the adder 203, the adder 203 is connected to the sawtooth wave generator 204, and the sawtooth wave generator 204 is connected to the comparator 205. The implementations of the first register 201, the second register 202, the adder 203, the sawtooth wave generator 204 and the comparator 205 may be the same as the first register 101, the second register 102, the adder 103, the sawtooth wave generator 104 and the comparator 105 of FIG. 1, respectively, their details are not repeated herein. In other words, the operation of the PWM control device 20 of the ultrasound control system 2 of one or more embodiments described below may be performed by the PWM control device 10 shown in FIG. 1. Additionally, the ultrasound control method of one or more embodiments described below may also be applied to the PWM control device 10 shown in FIG. 1.

The frequency compensator 21 and the sinusoidal signal generator 22 are connected to the comparator 205. Further, the frequency compensator 21 may be connected to an input b of the comparator 205, and the sinusoidal signal generator 22 may be connected to an output of the comparator 205. The frequency compensator 21 may include a phase-locked loop (PLL) frequency controller.

As shown in FIG. 3, the ultrasound control method includes: step S101: outputting, by a frequency compensator, an ultrasound control signal; step S103: adding, by an adder, a target pulse count and a remainder value to obtain a summed value; step S105: obtaining, by the adder, a maximum pulse count according to a system clock period; step S107: determining, by the adder, whether the summed value is smaller than the maximum pulse count; when the determination result of step S107 is “yes”, performing step S109: replacing, by the adder, the remainder value of the second register with the summed value; when the determination result of step S107 is “no”, performing step S111: replacing, by the adder, the remainder value of the second register with a difference value between the summed value and the maximum pulse count, and generating, by the adder, a pulse trigger signal; step S113: generating, by a sawtooth wave generator, a sawtooth wave signal based on the pulse trigger signal; step S115: determining, by a comparator, a pulse width according to a comparison result between the sawtooth wave signal and the ultrasound control signal, and outputting, by the comparator, a pulse width modulation signal based on the pulse width; and step S117: outputting, by a sinusoidal signal generator, a sinusoidal signal according to the pulse width modulation signal. The present disclosure does not limit the sequence of performing step S103 and step S105, step S103 may be performed after step S105 or may be performed at the same time as step S105. Even though FIG. 3 illustrates step S105 as performed after step S103, FIG. 3 does not intend to limit that step S105 can only be performed after the summed value is obtained.

In step S101, the frequency compensator 21 outputs the ultrasound control signal A1 to the comparator 205. The ultrasound control signal may be used to control the driving frequency and phase of the ultrasonic transducer. Specifically, the target sinusoidal signal may be a sinusoidal signal with a target frequency. The portion of the target sinusoidal signal corresponding to the negative half cycle may be inverted to positive values, forming a waveform with only positive values. In said waveform, the portion corresponding to the half cycle T1 may serve as the ultrasonic control signal A1.

In step S103, each time the system clock C1 occurs, the adder 203 adds the target pulse count stored by the first register 201 and the remainder value stored by the second register 202 to obtain the summed value. An initial value of the remainder value stored by the second register 202 may be 0.

In step S105, the adder 203 obtains the maximum pulse count according to the system clock period, wherein the maximum pulse count may be the highest number of pulse-width modulation signals that can be generated within a single cycle. The maximum pulse count may be determined by dividing the half cycle T1 of the target sinusoidal signal (the time interval between two system clock cycles C1 at start and end, as shown in the hatched area of FIG. 4) by the system clock period. For example, the frequency of the half cycle T1 may be twice the frequency of the target sinusoidal signal. In an example, if the system clock frequency is 100 MHz and the target sinusoidal signal frequency is 20 kHz, the number of system clock within the half cycle T1 of the target sinusoidal signal is 2500. Therefore, the target pulse count stored by the first register 201 may be less than the maximum pulse count 2500. The present disclosure is not limited to the numerical values listed here.

In step S107, the adder 203 determines whether the summed value is smaller than the maximum pulse count. The adder 203 replaces the remainder value of the second register 202 with the summed value in step S109 when determining the summed value is smaller than the maximum pulse count. In other words, after step S109, the remainder value stored in the second register 202 is the summed value. Further, after step S109, the adder 203 may perform step S103 again.

On the contrary, the adder 203 replaces the remainder value of the second register 202 with the difference value between the summed value and the maximum pulse count and generates the pulse trigger signal A2 in step S111 when determining the summed value is greater than or equal to the maximum pulse count. The pulse trigger signal A2 is configured to trigger the generation of the sawtooth wave signal. In other words, after step S111, the remainder value stored in the second register 202 is the difference value. It should be noted that in step S111, the adder 203 may replace the remainder value stored by the second register 202 with the difference value between the summed value and the maximum pulse count. For example, the difference value may be a value of the summed value subtracted by the maximum pulse count. In an embodiment, the adder 203 may only calculate the difference value between the summed value and the maximum pulse count when the summed value is greater than or equal to the maximum pulse count, and replace the remainder value of the second register 202 with the difference value.

For example, step S103, step S105, step S107, step S109 and step S111 may be implemented with the form of table 1 below. In table 1, the maximum pulse count is assumed to be 8, and the target pulse count is assumed to be 5. The value “1” in the column of the pulse trigger signal is used to represent generating one pulse trigger signal, and the symbol is used to represent that no pulse trigger signal is generated.

TABLE 1

| number of | | target | remainder | pulse |
|---|---|---|---|---|
| system | remainder | pulse | value stored by | trigger |
| clock | value | count | second register | signal |
| 1 | 0 | 5 | 5 | — |
| 2 | 5 | 5 | 2 | 1 |
| 3 | 2 | 5 | 7 | — |
| 4 | 7 | 5 | 4 | 1 |
| 5 | 4 | 5 | 1 | 1 |
| 6 | 1 | 5 | 6 | — |
| 7 | 6 | 5 | 3 | 1 |
| 8 | 3 | 5 | 0 | 1 |

As can be seen from table 1, the target pulse count stored by the first register 201 is 5. When the first system clock occurs, the remainder value stored by the second register 202 is 0, and the summed value is 5. Since the summed value is smaller than the maximum pulse count, no pulse trigger signal is generated, and the remainder value stored by the second register 202 is replaced by the summed value 5 before the second system clock occurs. Then, when the second system clock occurs, the remainder value stored by the second register 202 is 5, and the summed value is 10. Since the summed value is greater than the maximum pulse count, the adder 203 generates one pulse trigger signal, and the remainder value stored by the second register 202 is replaced by the difference value 2 between the summed value and the maximum pulse count before the third system clock occurs, and so on. Therefore, take FIG. 4 as an example, the system clock of number “2” in table 1 may correspond to the first pulse trigger signal A2, and the system clock of number “4” in table 1 may correspond to the second pulse trigger signal A2.

In step S113, the sawtooth wave generator 204 is triggered by the pulse trigger signal A2 to generate the sawtooth wave signal A3 and outputs the sawtooth wave signal A3 to the comparator 105. Further, the sawtooth wave generator 204 may be triggered by one pulse trigger signal A2 to generate one sawtooth wave signal A3. In step S115, the comparator 105 determines the pulse width according to the comparison result between the sawtooth wave signal A3 and the ultrasound control signal A1, and outputs the PWM signal based on the pulse width. Further, the duration of the ultrasound control signal A1 being greater than the sawtooth wave signal A3 is positively associated (for example, equal to) with the pulse width. Take FIG. 4 as an example, a partial signal B1 of the ultrasound control signal A1 is greater than a partial signal of the second sawtooth wave signal A3, and the duration of the partial signal B1 may be the pulse width of a corresponding PWM signal. Similarly, the pulse width of the next PWM signal may be the duration of the next partial signal B2 of the ultrasound control signal A1. Therefore, as can be seen from FIG. 4, the pulse widths of the PWM signals may be different from each other.

In step S117, the sinusoidal signal generator 22 outputs a sinusoidal signal according to the PWM signal.

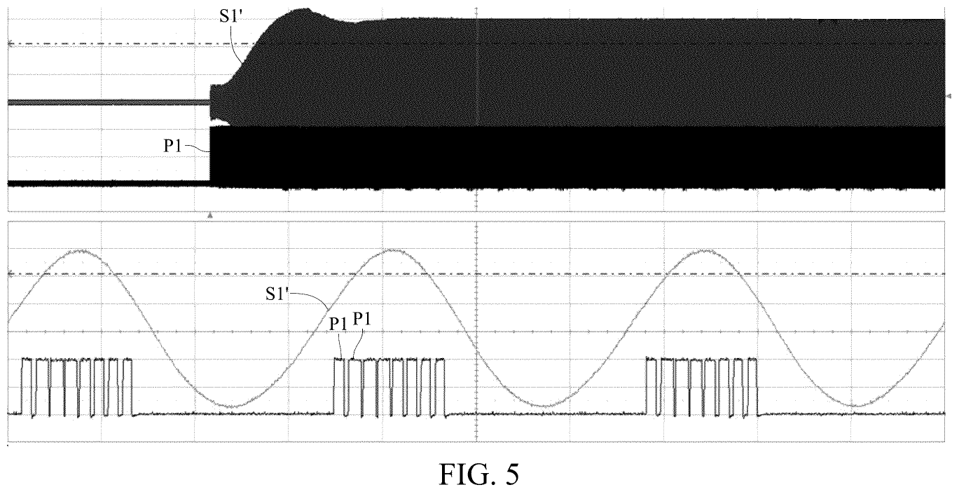

Please refer to FIG. 5, wherein FIG. 5 is a diagram showing the PWM signal and a sinusoidal signal. The upper part of FIG. 5 illustrates the envelope diagrams of the sinusoidal signal S1′ output by the sinusoidal signal generator and the PWM signal P1. The lower part of FIG. 5 shows the waveform diagrams of the sinusoidal signal S1′ output by the sinusoidal signal generator and the PWM signal P1. As shown in FIG. 5, the PWM signals P1 are pulse-shaped signals, and depending on the comparison result between the sawtooth wave signal and the ultrasound control signal, the PWM signals P1 may have different widths. The sinusoidal signal generator generates the sinusoidal signal S1′ based on the PWM signals P1.

Accordingly, the ultrasound control system and method according to one or more embodiments of the present disclosure may synchronize the sinusoidal signal of the target frequency with the frequency of the sawtooth wave signal of the ultrasound controller within each half cycle of the sinusoidal signal, thereby preventing the generation of excessive PWM signals or the omission of PWM signal. Accordingly, the stability and reliability of the frequency of the ultrasound control signal may be improved.

It should be noted that after step S117, the adder may perform step S103 again until the number of the pulse trigger signals generated by step S111 of FIG. 3 is equal to the target pulse count of step S103 when the determination result of step S107 of FIG. 3 is the summed value being greater than the maximum pulse count. When the number of the pulse trigger signals generated by step S111 of FIG. 3 is equal to the target pulse count of step S103, it means that the ultrasound control method reaches the control objective of a single cycle. Therefore, the ultrasound control method may end after the corresponding PWM signal and the sinusoidal signal are generated; or, step S101 may be performed again to generate the next ultrasound control signal and step S103 may be performed on said next ultrasound control signal.

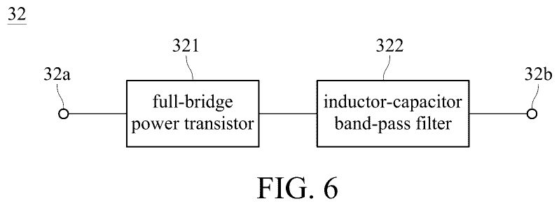

Please refer to FIG. 6, wherein FIG. 6 is a block diagram illustrating a sinusoidal signal generator according to an embodiment of the present disclosure. As shown in FIG. 6, the sinusoidal signal generator 32 may include a full-bridge power transistor 321 and an inductor-capacitor band-pass filter 322.

An input end 32a of the full-bridge power transistor 321 may be connected to an output end of the PWM control device, i.e. an output end of the comparator. An output end of the full-bridge power transistor 321 may be connected to an input end of the inductor-capacitor band-pass filter 322, and the inductor-capacitor band-pass filter 322 may have an output end 32b. The output end 32b may output the sine wave alternating current to the ultrasound transducer for the ultrasound transducer to convert the received sinusoidal signal into mechanical vibration. The full-bridge power transistor 321 may include an H-bridge transistor, and the inductor-capacitor band-pass filter 322 may include an inductor-inductor-capacitor-capacitor filter (LLCC filter).

Further, step S117 of FIG. 3 may include the full-bridge power transistor 321 switching a direct current voltage signal into an alternating current voltage signal according to the PWM signal; and the inductor-capacitor band-pass filter 322 filtering the alternating current voltage signal to generate the sinusoidal signal described above. Moreover, the inductor-capacitor band-pass filter 322 may output the sinusoidal signal to the ultrasound transducer through the output end 32b.

In an embodiment, the sinusoidal signal generator 32 may further include a transformer connected between the output end 32b of the inductor-capacitor band-pass filter 322 and the ultrasound transducer. Step S117 of FIG. 3 may further include raising, by the transformer, the sinusoidal signal to the driving voltage required for the ultrasound controller to output power.

In view of the above description, the PWM signal generated by the PWM control device according to one or more embodiments of the present disclosure may be used in conjunction with a sinusoidal signal generator to generate alternating current (AC) voltage with specific sine wave frequency. The AC voltage is then converted into vibrational mechanical energy by the ultrasonic transducer. Accordingly, since the amplitude of the target sinusoidal signal is positively correlated with the pulse width of the PWM signal, the PWM control device according to one or more embodiments of the present disclosure may control the output power of the ultrasound controller by adjusting the voltage (amplitude) of the target sinusoidal signal. At the same time, based on the summed value of the target pulse count and the remainder value stored in the registers, the pulse trigger signal is output, enabling synchronization between the PWM signal and the sinusoidal signal, to ensure that the expected number of PWM signals is generated within a unit cycle, thereby aligning the output PWM signal with the half cycle of the sinusoidal signal to be controlled. As a result, the issue of asynchronous PWM signal affecting output frequency stability and reliability may be resolved. Further, the ultrasound control system and method according to one or more embodiments of the present disclosure may synchronize the sinusoidal signal of the target frequency with the frequency of the sawtooth wave signal of the ultrasound controller within each half cycle of the sinusoidal signal, thereby preventing the generation of excessive PWM signals or the omission of PWM signal. Accordingly, the stability and reliability of the frequency of the ultrasound control signal may be improved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A pulse width modulation control device, comprising:
a first register configured to store a target pulse count;
a second register configured to store a remainder value;
an adder connected to the first register and the second register, the adder configured to obtain a maximum pulse count according to a system clock period, add the target pulse count and the remainder value to obtain a summed value each time a system clock occurs, replace the remainder value of the second register with the summed value when the summed value is smaller than the maximum pulse count, replace the remainder value of the second register with a difference value between the summed value and the maximum pulse count and generate a pulse trigger signal when the summed value is greater than or equal to the maximum pulse count;
a sawtooth wave generator connected to the adder, the sawtooth wave generator configured to generate a sawtooth wave signal based on the pulse trigger signal; and
a comparator connected to the sawtooth wave generator, the comparator configured to determine a pulse width according to a comparison result between the sawtooth wave signal and an ultrasound control signal, and output a pulse width modulation signal based on the pulse width.

2. The pulse width modulation control device according to claim 1, wherein the maximum pulse count is a value obtained by dividing a half cycle of a target sinusoidal signal by the system clock period.

3. An ultrasound control system, comprising:
a frequency compensator configured to output an ultrasound control signal;
a pulse width modulation control device connected to the frequency compensator, the pulse width modulation control device comprising:
a first register configured to store a target pulse count;
a second register configured to store a remainder value;
an adder connected to the first register and the second register, the adder configured to obtain a maximum pulse count according to a system clock period, add the target pulse count and the remainder value to obtain a summed value each time a system clock occurs, replace the remainder value of the second register with the summed value when the summed value is smaller than the maximum pulse count, replace the remainder value of the second register with a difference value between the summed value and the maximum pulse count and generate a pulse trigger signal when the summed value is greater than or equal to the maximum pulse count;
a sawtooth wave generator connected to the adder, the sawtooth wave generator configured to generate a sawtooth wave signal based on the pulse trigger signal; and
a comparator connected to the sawtooth wave generator, the comparator configured to determine a pulse width according to a comparison result between the sawtooth wave signal and the ultrasound control signal, and output a pulse width modulation signal based on the pulse width; and
a sinusoidal signal generator connected to the pulse width modulation control device, the sinusoidal signal generator configured to output a sinusoidal signal according to the pulse width modulation signal.

4. The ultrasound control system according to claim 3, wherein the sinusoidal signal generator comprises:
a full-bridge power transistor connected to the pulse width modulation control device, the full-bridge power transistor configured to switch a direct current voltage signal into an alternating current voltage signal according to the pulse width modulation signal; and
an inductor-capacitor band-pass filter connected to the full-bridge power transistor, the inductor-capacitor band-pass filter configured to filter the alternating current voltage signal to generate the sinusoidal signal.

5. The ultrasound control system according to claim 3, wherein the maximum pulse count is a value obtained by dividing a half cycle of a target sinusoidal signal by the system clock period.

6. An ultrasound control method, comprising:
outputting, by a frequency compensator, an ultrasound control signal;
adding, by an adder, a target pulse count and a remainder value to obtain a summed value;
obtaining, by the adder, a maximum pulse count according to a system clock period;
replacing, by the adder, the remainder value with the summed value when determining, by the adder, the summed value is smaller than the maximum pulse count;
replacing, by the adder, the remainder value with a difference value between the summed value and the maximum pulse count and generating, by the adder, a pulse trigger signal when determining, by the adder, the summed value is greater than or equal to the maximum pulse count;
generating, by a sawtooth wave generator, a sawtooth wave signal based on the pulse trigger signal;
determining, by a comparator, a pulse width according to a comparison result between the sawtooth wave signal and the ultrasound control signal, and outputting, by the comparator, a pulse width modulation signal based on the pulse width; and
outputting, by a sinusoidal signal generator, a sinusoidal signal according to the pulse width modulation signal.

7. The ultrasound control method according to claim 6, wherein outputting, by the sinusoidal signal generator, the sinusoidal signal according to the pulse width modulation signal comprises:
switching, by a full-bridge power transistor, a direct current voltage signal into an alternating current voltage signal according to the pulse width modulation signal; and
filtering, by an inductor-capacitor band-pass filter, the alternating current voltage signal to generate the sinusoidal signal.

8. The ultrasound control method according to claim 6, wherein the maximum pulse count is a value obtained by dividing a half cycle of a target sinusoidal signal by the system clock period.
